(19) United States
(12) Patent Application Publication
(10) Pub. No.: US 2023/0129809 A1
(43) Pub. Date: Apr. 27, 2023

(54) CHAMBER DEVICE, WAFER HANDLING APPARATUS AND METHOD FOR PROCESSING WAFER

(71) Applicant: Zhongke Jingyuan Electron Limited, Beijing (CN), Beijing (CN)

(72) Inventor: Lei JIANG, Beijing (CN)

(21) Appl. No.: 17/907,578

(22) PCT Filed: May 28, 2021
(86) PCT No.: PCT/CN2021/096749

§ 371 Date: Sep. 28, 2022

(30) Foreign Application Priority Data
Dec. 31, 2020 (CN) 202011639567.5

(51) Int. Cl. H01L 21/677; H01L 21/67

(52) U.S. Cl. CPC H01L 21/67742; H01L 21/67253

(57) ABSTRACT

The present disclosure provides a chamber device, which includes a housing, which defines an cavity therein, a first valve, provided on a first side of the housing, and configured to switch between a closed condition thereof, and an opened condition thereof where the housing is in communication with one of the first pressure environment and the second pressure environment therethrough, a switching device, fixed to the housing, and configured to align the first valve with a respective inlet of the one of the first pressure environment and the second pressure environment, a second valve, provided on a second side of the housing opposite to the first side, and configured to communicate the cavity with the first pressure environment or disconnect the cavity from the first pressure environment, and a pressure regulating device, provided on the housing and in communication with the cavity .

### CROSS-REFERENCE TO RELATED APPLICATION

This application is a Section 371 National Stage Application of International Application No. PCT/CN2021/096749 filed on May 28, 2021, entitled “CHAMBER DEVICE, WAFER HANDLING APPARATUS AND METHOD FOR PROCESSING WAFER ”, which claims priority to Chinese Patent Application Invention No. 202011639567.5 filed on Dec. 31, 2020 in the China National Intellectual Property Administration, the whole disclosure of which is incorporated herein by reference.

### BACKGROUND

### Field

Embodiments of the present disclosure generally relate to the technical field of semiconductor technology, and more particularly to a chamber device, a wafer handling apparatus, and a method for processing a wafer using the wafer handling apparatus; more particularly, it relates to a chamber device for transferring a wafer between a first pressure environment and a second pressure environment, a wafer handling apparatus, and a method for processing wafer using the wafer handling apparatus.

### Description of Relevant Art

In recent years, in semiconductor industry, it is typically required to perform detection process on wafer such as silicon wafer and the like by using an electron beam detection apparatus in a high vacuum environment.

In order to improve yield of the electron beam detection operating in a high vacuum condition, then it is generally required to add a vacuum interlock cavity between a working cavity of the electron beam detection apparatus and a wafer carrier box at an atmospheric environment. The working chamber of the electron beam detection apparatus is relatively large, and it takes a relatively long time to be vacuumized to a high degree of vacuum. And the vacuum interlock cavity is designed to be relatively compact and is much smaller than that of the working cavity. As such, it takes a much less time to vacuumize the working chamber to a high degree of vacuum, so as to increase the yield of the electron beam detection apparatus. In addition, in the field of detection of semiconductor wafer, it is required to avoid damage and contamination of wafer during detection process thereof, that is to say, it is required to ensure safety of wafer during the detection process thereof. Therefore, there is an urgent need for a vacuum interlock chamber which is not only relatively small in volume, but also is equipped with a device for detection of wafer status.

### SUMMARY

The embodiments of the present disclosure have been made to overcome or alleviate at least one aspect of the aforementioned disadvantages and/or shortcomings in the prior art, by providing a chamber device, a wafer handling apparatus, and a method for processing wafer using the wafer handling apparatus.

Following technical solutions are adopted in exemplary embodiments of the invention.

According to an aspect of the present disclosure, there is provided a chamber device which is configured to transfer a plurality of wafers between a first pressure environment and a second pressure environment, comprising: a housing, which defines an cavity therein; a first valve, provided on a first side of the housing, and configured to switch between a closed condition thereof, and an opened condition thereof where the housing is in communication with one of the first pressure environment and the second pressure environment therethrough; a switching device, fixed to the housing, and configured to align the first valve with a respective inlet of the one of the first pressure environment and the second pressure environment; a second valve, provided on a second side of the housing opposite to the first side, and configured to communicate the cavity with the first pressure environment or disconnect the cavity from the first pressure environment; and a pressure regulating device, provided on the housing and in communication with the cavity, and configured to adapt an intensity of pressure within the cavity to be substantially the same as that of the first pressure environment or the second pressure environment. The chamber device further comprises a wafer supporting device provided inside the cavity and being formed into a multi-layer supporting structure, each layer of which is configured to support a respective wafer of the plurality of wafers respectively, in one-to-one correspondence.

According to an embodiment of the present disclosure, the multi-layer supporting structure comprises a first supporting half and a second supporting half. The first supporting half comprises a first support fixed to a bottom inner surface of the housing and an inner wall at a third side of the housing intersecting both the first side and the second side, and a plurality of first pillars protruding from the first support inwards the cavity. The second supporting half comprises a second support fixed to the bottom inner surface of the housing and an inner wall at a fourth side of the housing opposite to the third side, and a plurality of second pillars protruding from the second support inwards the cavity. Moreover, respective first pillars of the plurality of first pillars and respective second pillars of the plurality of second pillars both located in each single layer of the multi-layer supporting structure jointly support the respective wafer of the plurality of wafers which is to be supported in the same single layer, and respective axes of the respective first pillars and the respective second pillars are arranged to be co-planar with each other and parallel to the bottom inner surface of the housing.

According to an embodiment of the present disclosure, each of both a distance between two adjacent first pillars, which are located respectively in two adjacent layers of the multi-layer supporting structure, of the plurality of first pillars, and a distance between two adjacent second pillars, which are located respectively in two adjacent layers of the multi-layer supporting structure, of the plurality of first pillars, is larger than a thickness of each wafer in the plurality of wafers.

According to an embodiment of the present disclosure, the chamber device further comprises a first wafer detection device, which comprises: a first light source, mounted to the housing and configured to emit a first irradiation beam into the cavity; a plurality of groups of first sensors mounted to the housing and arranged to be at least partially aligned in one-to-one correspondence with layers of the multi-layer supporting structure respectively , and configured to sense the first irradiation beam and in turn generate a plurality of first electrical signals based on sensed results; and a processing circuit, electrically connected with the plurality of groups of first sensors, and configured to receive the plurality of first electrical signals and to determine whether a respective single layer of the multi-layer supporting structure provided corresponding to each group of the plurality of groups of first sensors supports therein a respective wafer of the plurality of wafers, based on the plurality of first electrical signals.

According to an embodiment of the present disclosure, each group of the plurality of groups of first sensors is configured to generate a respective first electrical signal, which has one of a high level and a low level as a first magnitude of the respective first electrical signal in response to a condition where the first irradiation beam is not received thereby, and has the other one of the high level and the low level as a as a second magnitude of the respective first electrical signal in response to a condition where the first irradiation beam is at least partially received thereby; and the processing circuit is configured to determine, depending on the respective first electrical signal output by each group of the plurality of groups of first sensors at least partially aligned in one-to-one correspondence with a respective layer in the multi-layer supporting structure, that said layer supports the respective wafer thereon in response to the first magnitude of the respective first electrical signal and said layer fails to support the respective wafer thereon in response to the second magnitude of the respective first electrical signal.

According to an embodiment of the present disclosure, the chamber device further comprises a second wafer detection device, which comprises: a plurality of second light sources, mounted on one of upper side and lower side of the housing, and arranged to define an imaginary circle having a center of circle coincident with respective expected positions of respective centers of circle of the plurality of wafers, the plurality of second light sources being arranged to spaced apart from each other at a same angular interval in a circumferential direction of the imaginary circle and configured to emit a second irradiation beam into the cavity respectively; and a plurality of second sensors, provided on the other one of the upper side and lower side, and substantially aligned in one-to-one correspondence with the plurality of second light sources, and configured to sense respectively the second irradiation beam from the plurality of second light sources so as to generate a plurality of second electrical signals based thereon. The plurality of second light sources are arranged such that a difference between a distance between respective centers of the plurality of second light sources and the center of circle of the imaginary circle and a radius of the wafer to be placed of the plurality of wafers is less than a preset tolerance which is offset from respective center of said wafer to be placed, and the processing circuit is also electrically connected with the plurality of second sensors, and is configured to receive the plurality of second electrical signals and to determine whether respective center of at least one wafer of the plurality of wafers is offset from the respective expected positions depending on the plurality of second electrical signals.

According to an embodiment of the present disclosure, each second sensor is configured to generate a respective second electrical signal, which has one of a high level and a low level as a first magnitude of the respective second electrical signal in response to a condition where the second irradiation beam is not received thereby, and has the other one of the high level and the low level as a second magnitude of the respective second electrical signal in response to a condition where the second irradiation beam is at least partially received thereby; and the processing circuit is configured to determine, depending on the plurality of second electrical signals output respectively by the plurality of second sensors, that respective center of at least one wafer of the plurality of wafers is offset from respective one of the expected positions of the plurality of wafers in response to the first magnitude of the respective second electrical signal from at least one second sensor of the plurality of second sensors.

According to an embodiment of the present disclosure, the chamber device further comprises a distance sensor which is based on a photoelectric-conversion and is arranged concentric with the center of circle of the imaginary circle and adjacent to the plurality of second light sources, the distance sensor being configured to determine, depending on the second irradiation beam which is reflected from at least one of the plurality of wafers and then received by the distance sensor, a distance between the wafer at which the second irradiation beam is reflected back and the respective second light source; and in a condition that the processing circuit determine that at least one wafer is offset from the respective one of the expected positions of the plurality of wafers, the processing circuit is further configured to determine, depending on the distance as measured by the distance sensor, on which layer of the multi-layer supporting structure the respective wafer of the plurality of wafers is placed, whose center is offset from the respective one of the expected positions of the plurality of wafers.

According to an embodiment of the present disclosure, in a condition that an axial direction of respective axes of the plurality of first pillars and the plurality of second pillars is set to be a longitudinal direction, then, in a transverse direction orthogonal to the longitudinal direction, both a minimal transverse distance between respective first pillars of the plurality of first pillars and a minimal transverse distance between respective second pillars of the plurality of second pillars in the same single layer of the multi-layer supporting structure are set to be not larger than a maximum transverse distance threshold which is defined to be a center distance of two light sources adjacent to each other in the transverse direction of the plurality of second light sources.

According to an embodiment of the present disclosure, a wavelength range of a portion of the second irradiation beam received by the plurality of second sensors and a wavelength range of a portion of the first irradiation beam received by the plurality of groups of first sensors do not overlap with each other.

Moreover, according to another aspect of the present disclosure, there is provided a wafer handling apparatus, comprising: the chamber device as above; a first robotic arm arranged in the first pressure environment and adjacent to the first valve, and configured to transfer the plurality of wafers between the first pressure environment and the chamber device through the first valve; and a second robotic arm arranged in the second pressure environment and adjacent to the second valve, and configured to transfer the plurality of wafers between the second pressure environment and the chamber device through the second valve.

Furthermore, according to still another aspect of the present disclosure, there is provided a method for processing wafer using the wafer handling apparatus as above, comprising: opening the first valve such that the first pressure environment and the cavity are at substantially the same intensity of pressure, loading the plurality of wafers onto respective layers of the multi-layer supporting structure via the first robotic arm respectively, and adjusting respective positions of the plurality of wafers to the expected positions of the plurality of wafers depending on output of the processing circuit; cutting off the first valve and vacuumizing the cavity to a degree of vacuum which is substantially the same as that of the second pressure environment, after the plurality of wafers are loaded onto the multi-layer supporting structure; and opening the second valve and transferring the plurality of wafers from the cavity to the second pressure environment by the second robotic arm.

According to an embodiment of the present disclosure, the method for processing wafer further comprises: transferring the plurality of wafers into the cavity and loading the plurality of wafers onto respective layers of the multi-layer supporting structure respectively by the second robotic arm, and adjusting the respective positions of the plurality of wafers to the expected positions of the plurality of wafers depending on the output of the processing circuit, after subsequent processes of the plurality of wafers in the second pressure environment are completed; cutting off the second valve and inflating the cavity to an intensity of pressure which is substantially the same as that of the first pressure environment; and opening the first valve and transferring the plurality of wafers out of the cavity to the first pressure environment by the first robotic arm.

In addition, according to yet another aspect of the present disclosure, there is provided an electron beam detection apparatus, comprising: the wafer handling apparatus as above; and a second housing, defining a vacuum chamber therein which functions as the second pressure environment, the vacuum chamber being equipped with an electron beam detection device therein which comprises a scanning electron microscope.

### BRIEF DESCRIPTION OF THE DRAWINGS

Embodiments of the present disclosure will now be described, merely by way of example, with reference to the accompanying schematic drawings, in which the corresponding reference numerals represent the corresponding components. A brief description of the drawings is as follows:

FIGS. 1A and 1B schematically illustrate a stereoscopic structural view of a chamber device, which is configured to transfer wafer between a first pressure environment and a second pressure environment, according to embodiments of the disclosure from different perspectives, respectively;

FIG. 2 illustrates a schematic structural view of a multi-layer supporting structure in the chamber device as illustrated in FIGS. 1;

FIG. 3 illustrates a structure of a first wafer detection device, and a relative positioning relationship of the first wafer detection device with respect to the multi-layer supporting structure and a plurality of wafers;

FIG. 4 illustrates the structure of a second wafer detection device, and a relative positioning relationship of the second wafer detection device with respect to the multi-layer supporting structure and the wafer;

FIG. 5 illustrates a schematic structural view of a wafer handling apparatus according to embodiments of the disclosure;

FIG. 6 illustrates a flowchart of a method for processing wafer using the wafer handling apparatus; and

FIG. 7 illustrates a schematic structural view of the electron beam detection apparatus according to embodiments of the disclosure.

### DETAILED DESCRIPTION OF EMBODIMENTS

Technical solution of the present disclosure will be further explained in detail through the embodiments in combination with the accompanying drawings. In the specification, same or similar reference numerals and alphabets indicate same or similar components. Following description of the embodiments of the present disclosure with reference to the accompanying drawings is intended to explain overall inventive concept of the present disclosure, rather than a limitation of the present disclosure.

The accompanying drawings are used to illustrate the contents of embodiments of the present disclosure. Dimensions and shapes of the components in the drawings do not demonstrate true scales of components of a chamber device and a wafer handling apparatus.

FIGS. 1A and 1B schematically illustrate a stereoscopic structural view of a chamber device 1, which is configured to transfer wafer between a first pressure environment and a second pressure environment, according to embodiments of the disclosure from different perspectives, respectively.

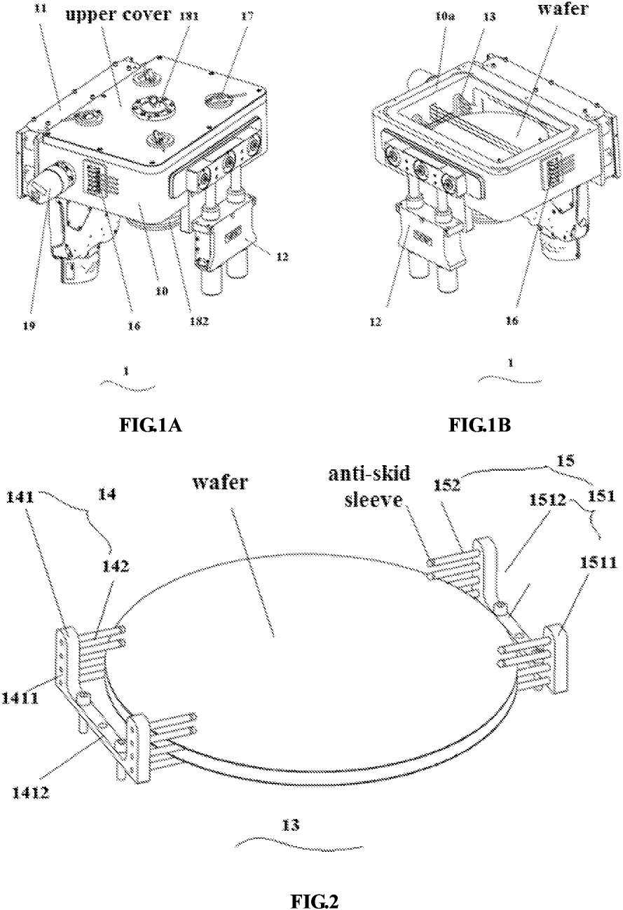

Thus, according to the overall technical concept of embodiments of the present disclosure, as illustrated in FIGS. 1A and 1B and FIG. 2, in one aspect of the embodiments of the present disclosure, there is provided a chamber device which is configured to transfer a plurality of wafers between a first pressure environment (e.g., an atmospheric environment, or a wafer carrier box in an atmospheric environment) and a second pressure environment (e.g., a vacuum chamber configured to perform a detection of wafer), comprising: a housing 10, which defines an cavity 10a therein; a first valve 11, provided on a first side of the housing 10, and configured to switch between a closed condition thereof, and an opened condition thereof where the housing is in communication with the first pressure environment or the second pressure environment therethrough (and in the opened condition, it is allowed that a wafer may be loaded into the cavity and removed from the cavity, such that the first valve functions as a wafer transfer valve); a switching device, fixed to the housing 10 and configured to align the first valve 11 with a respective inlet of the first pressure environment or the second pressure environment; a second valve 12, provided on a second side of the housing opposite to the first side, and configured to communicate the cavity with the first pressure environment or disconnect the cavity from the first pressure environment; and a pressure regulating device, provided on the housing 10 and in communication with the cavity 10a, and configured to adapt an intensity of pressure within the cavity 10a to be substantially the same as that of the first pressure environment or the second pressure environment.

By way of example, the first valve 12 is a transfer valve configured to connect and communicate the chamber device 1 with the ambient.

Moreover, for example, the second valve 12 is an atmospheric valve configured to isolate the chamber device 1 from the ambient, and to communicate the chamber device 1 with the ambient.

In specific embodiments of the present disclosure, for example, the switching device is a motion device, such as a rotary device (e.g., a turntable) which aligns the first valve 11 with the respective inlet of the first pressure environment or the second pressure environment by rotating the housing 10; or the switching device is a translation device, such as a linear motor or a two-dimensional workbench or stage, which aligns the first valve 11 with the respective inlet of the first pressure environment or the second pressure environment by translating the housing 10.

In specific embodiments of the disclosure, by way of example, the pressure regulating device of the chamber device 1 specifically comprises: an inflation port 181, connected to a gas source or the first pressure environment, and configured to inflate the cavity 10a to an intensity of pressure which is substantially equalized with that of the first pressure environment; an gas-suction port 182, connected to a vacuum source or the second pressure environment, and configured to vacuumize the cavity to a degree of vacuum which is set by the processing circuit 163 or is substantially the same as that of the second pressure environment; and a vacuum gauge 19, which communicates with the cavity 10a, and is configured to measure the degree of vacuum of the cavity. By way of example, vacuumizing of the cavity 10a through the gas-suction port 182 is controlled, depending on results of measurement by the vacuum gauge 19.

In embodiments of the present disclosure, by way of example, the chamber device 1 further comprises a wafer supporting device provided inside the cavity 10a, the wafer supporting device comprises a multi-layer supporting structure 13, each layer of which is configured to support a respective wafer of the plurality of wafers respectively, in one-to-one correspondence.

Since the wafer supporting device is capable of supporting the plurality of wafers, then, the chamber device of embodiments of the disclosure may be used so as to improve efficiency.

FIG. 2 illustrates a schematic structural view of a multi-layer supporting structure 13 in the chamber device as illustrated in FIGS. 1A and 1B.

In embodiments of the disclosure, by way of example, the multi-layer supporting structure 13 comprises a first supporting half 14 and a second supporting half 14. As illustrated in FIG. 2, more specifically, by way of example, the first supporting half 14 comprises: a first support 141, fixed to a bottom inner surface of the housing 10, and to an inner wall at a third side of the housing intersecting both the first side and the second side; and a plurality of first pillars 142 protruding from the first support 141 inwards the cavity 10a. And by way of example, the second supporting half 15 comprises: a second support 151, fixed to the bottom inner surface of the housing 10, and to an inner wall at a fourth side of the housing opposite to the third side; and a plurality of second pillars 152 protruding from the second support 151 inwards the cavity 10a.

By way of example, respective first pillars of the plurality of first pillars 142 and respective second pillars of the plurality of second pillars 152 both located in each single layer of the multi-layer supporting structure 13 jointly support the respective wafer of the plurality of wafers which is to be supported in the same single layer, and respective axes of the respective first pillars and the respective second pillars are arranged to be co-planar with each other and parallel to the bottom inner surface of the housing 10. Thereby, the plurality of wafers are supported in layers of the multi-layer supporting structure 13, i.e., respective first pillars of the plurality of first pillars 142 and respective second pillars of the plurality of second pillars 152 both located in any one single layer of the multi-layer supporting structure 13 cooperate with each other to jointly support a respective wafer to be supported in such layer, of the plurality of wafers. As such, a layered supporting for the plurality of wafers may be realized with a simplified structure.

By way of example, respective free end of each of the plurality of first pillars 142 and/or the plurality of second pillars 152 directing inwards the cavity 10a is provided with a respective anti-skid sleeve, i.e., a skid-proof/skid-resistant sleeve, which is typically of a skid-resist material such as fluororubber and the like, so as to prevent or completely avoid sliding of the respective wafer supported there, as much as possible by utilizing its relatively large friction coefficient.

For example, the first support 141 and the second support 151 are fixed to the inner wall of the housing 10 by screw threaded connection, for example, or engaged into (for example, a pre-formed recess of) the inner wall of the housing 10 by positive fit implemented by clamping, and mounted in place by means of, for example, interference fit.

Alternatively or in additionally, for example, respective base portion of each of the plurality of first pillars 142 and the plurality of second pillars 152 is formed with external screw thread (i.e., male screw thread), and respective positions of the first support 141 and the second support 142 for mounting the plurality of first pillars 142 and the plurality of second pillars 152 are for example formed with holes, such as unthreaded holes, threaded holes having respective internal threads, or the like. As such, a respective base portion of each of the plurality of first pillars 142 and the plurality of second pillars 152 is screwed into and mounted into a respective hole and securely/firmly fixed in place there.

With aforementioned arrangement, it is ensured that the multi-layer supporting structure 13 firmly mounted to the inner wall of the housing 10 is used to stably support the plurality of wafers.

As a further embodiment, as illustrated in FIG. 2, by way of example, the first support 141 comprises: two first blocks 1411, both being fixed on the inner wall at the third side of the housing and spaced apart from each other; and a first rib 1412 connected between the two first blocks 1411, and fixed to the bottom inner surface of the housing 10. Moreover, for example, the second support 151 comprises: two second blocks 1511, both being fixed on the inner wall at the fourth side of the housing and spaced apart from each other; and a second rib 1512 connected between the two second blocks 1511, and fixed to the bottom inner surface of the housing 10.

By way of example, the first rib 1412 and the two first blocks 1411 are formed respectively, and then bonded, or assembled together by clamping or screw threaded connection, or formed integrally. For example, the second rib 1512 and the two second blocks 1511 are formed respectively, and then bonded, or assembled together by clamping or screw threaded connection, or formed integrally. No specific limitation/restriction is made thereto.

In embodiments of the present disclosure, for example, each of both a distance between two adjacent first pillars 142, which are located respectively in two adjacent layers of the multi-layer supporting structure, of the plurality of first pillars, and a distance between two adjacent second pillars 152, which are located respectively in two adjacent layers of the multi-layer supporting structure, of the plurality of first pillars, is larger than a thickness of each wafer in the plurality of wafers, so as to ensure that the plurality of wafers are smoothly placed into gaps each formed between pillars of adjacent layers, respectively.

In addition, in a further embodiment of the present disclosure, for example, in a condition that an axial direction of respective axes of the plurality of first pillars and the plurality of second pillars is set to be a longitudinal direction, then, in a transverse direction orthogonal to the longitudinal direction, both a minimal transverse distance between respective first pillars of the plurality of first pillars 142 and a minimal transverse distance between respective second pillars of the plurality of second pillars 152 in the same single layer of the multi-layer supporting structure are set to be not less than a minimal transverse distance threshold which is defined to be a diameter of a wafer having a minimal dimensional specification in the plurality of wafers having different dimensional specifications which is bearable by the multi-layer supporting structure 13, so as to facilitate supporting the plurality of wafers of various shapes or dimensional specifications compatibly.

Moreover, by way of example, as illustrated in FIG. 2, each single layer of the multi-layer supporting structure 13 is merely provided with: two respective first pillars of the plurality of first pillars 142, both being located on the two first blocks 1411, respectively; and two respective second pillars of the plurality of second pillars 152, both being located on the two second blocks 1511, respectively; and in all layers of the multi-layer supporting structure 13, respective axes of first pillars 142 located on the same first block of the two first blocks 1411 respectively are arranged to be co-planar with each other, and/or respective axes of second pillars 152 located on the same second block of the two second blocks 1511 respectively are arranged to be co-planar with each other. As such, for example, a total of 16 pillars may be divided into four groups. And respective four pillars in each group load/carry the same wafer in a coplanar manner. As such, four stacked wafers are supported. Once the plurality of wafers are placed in the multi-layer support structure 13, they directly contact the anti-skid sleeve provided at and sleeved on free ends of the pillars of respective group, so as to minimize a risk of wafer deviation/offset.

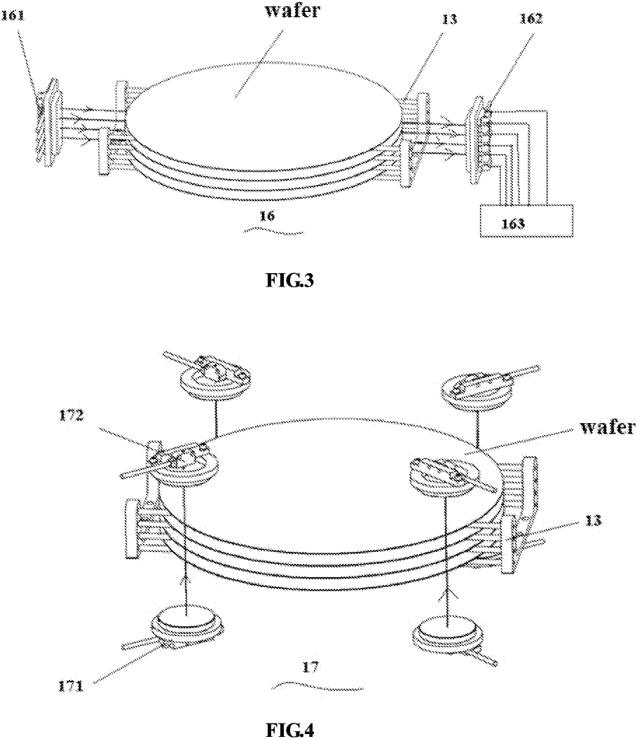

FIG. 3 illustrates a structure of a first wafer detection device 16, and a relative positioning relationship of the first wafer detection device 16 with respect to the multi-layer supporting structure 13 and the plurality of wafers.

In embodiments of the present disclosure, for example, the chamber device 1 further comprises a first wafer detection device 16, comprising: a first light source 161, mounted to the housing 10 and configured to emit a first irradiation beam into the cavity 10a; a plurality of groups of first sensors 162 mounted to the housing 10 and arranged to be at least partially aligned in one-to-one correspondence with layers of the multi-layer supporting structure 13 respectively (i.e., specifically, each group being arranged to be at least partially aligned in one-to-one correspondence with a respective single layer of the multi-layer supporting structure, respectively), and configured to sense the first irradiation beam and in turn generate a plurality of first electrical signals based on sensed results; and a processing circuit 163, electrically connected with the plurality of groups of first sensors 162, and configured to receive the plurality of first electrical signals and to determine whether a respective single layer of the multi-layer supporting structure 13 provided corresponding to each group of the plurality of groups of first sensors 152 supports therein a respective wafer of the plurality of wafers, based on the plurality of first electrical signals.

In a more specific embodiment, by way of example, each group of the plurality of groups of first sensors 162 is configured to generate a respective first electrical signal, which has one of a high level and a low level as a first magnitude of the respective first electrical signal in response to a condition where the first irradiation beam is not received thereby, and has the other one of the high level and the low level as a as a second magnitude of the respective first electrical signal in response to a condition where the first irradiation beam is at least partially received thereby. And moreover, the processing circuit 163 is configured to determine, depending on the respective first electrical signal output by each group of the plurality of groups of first sensors 162 at least partially aligned in one-to-one correspondence with a respective layer in the multi-layer supporting structure 13, that said layer supports the respective wafer thereon in response to the first magnitude of the respective first electrical signal and said layer fails to support the respective wafer thereon in response to the second magnitude of the respective first electrical signal.

In other words, the first magnitude of the respective first electrical signal indicates that the respective group of the plurality of groups of first sensors 162 fails to receive the first irradiation beam, i.e., an optical path of the first irradiation beam to the respective group of the plurality of groups of first sensors 162 is blocked, for example by the respective wafer loaded/carried by the respective layer; that is to say, it is determined that there necessarily exists a wafer on said layer. In such a condition, it is not necessary to separately perform a step of supplementary loading at least one additional wafer to said layer.

On the contrary, the second magnitude of the respective first electrical signal indicates that the respective group of the plurality of groups of first sensors 162 receives the first irradiation beam, i.e., an optical path of the first irradiation beam to the respective group of the plurality of groups of first sensors 162 is not blocked; that is to say, there exists no wafer on said layer (or alternatively, there is a wafer on said layer but the wafer fails to be disposed in place normally, for example, there occurs a phenomenon in which a center of the wafer is offset from (i.e., deviates from) an expected central position thereof, then an additional determination/judgment is required, e.g., as further depicted hereinafter). In such a condition, said layer may be idle, i.e., a space which is adapted to accommodate at least one wafer additionally loaded may be required.

With a simple setting of the first wafer detection device 16 as above, it may be determined that, there must be a condition in which at least one wafer necessarily exists on a specific layer in the multi-layer supporting structure 13, such that in this condition, there is no need to perform a step of supplementary loading at least one additional wafer to said layer. That is to say, the first wafer detection device 16 functions as “a detector configured to detect existence of wafer”.

In a specific embodiment, for example, the first support 141 is provided with a notch opening towards an upper surface of the housing 10, and the third side is formed with a first window therethrough which at least partially overlaps with the notch. And accordingly, the first light source 161 is arranged to be aligned with the first window and configured to emit the first irradiation beam into the cavity 10a through the first window.

As such, with such an arrangement in which the notch is aligned with the first window, the first irradiation beam emitted by the first light source 161 may be transferred into the cavity 10a without any obstruction.

For example, the first light source 161 comprises: a laser, an LED, or a hybrid light source of a laser and an LED.

By way of example, the first light source 161 for example merely comprises a single light source. Additionally or alternatively, for example, the first light source 161 comprises a plurality of light-emitting arranged in an array, and the plurality of groups of first sensors 162 comprise a plurality of first sensors 162 which are arranged in array and at least partially aligned with the plurality of light-emitting devices in one-to-one correspondence.

Accordingly, for example, the plurality of first sensors 162 are photosensitive sensors, e.g., photoelectric sensors or transducers each of which converts an optical signal of a specific wavelength (laser, LED light, or mixed light of both laser and LED light) into a respective electrical signal.

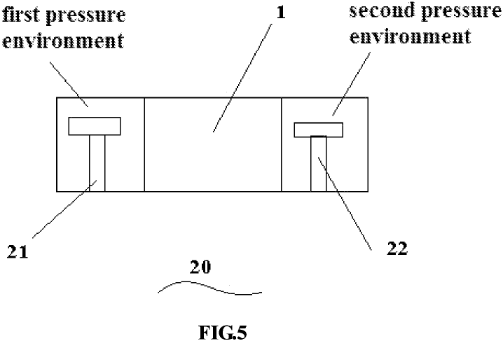

FIG. 4 illustrates the structure of a second wafer detection device 17, and a relative positioning relationship of the second wafer detection device 17 with respect to the multi-layer supporting structure 13 and the wafer.

In embodiments of the disclosure, for example, the chamber device 1 further comprises a second wafer detection device 17, which comprises: a plurality of second light sources 171, mounted on one of upper side and lower side of the housing 10, and arranged to define an imaginary circle (i.e. a virtual circle) having a center of circle coincident with respective expected positions of respective centers of circle of the plurality of wafers, the plurality of second light sources being arranged to spaced apart from each other at a same angular interval in a circumferential direction of the imaginary circle and configured to emit a second irradiation beam into the cavity respectively; and a plurality of second sensors 172, provided on the other one of the upper side and lower side of the housing 10 , and substantially aligned in one-to-one correspondence with the plurality of second light sources 171, and configured to sense respectively the second irradiation beam from the plurality of second light sources 171 so as to generate a plurality of second electrical signals based thereon.

In more specific embodiments, for example, for example, the plurality of second light sources 171 are arranged such that a difference between a distance (i.e., a radius of the imaginary circle) between respective centers of the plurality of second light sources and the center of circle of the imaginary circle and a radius of the wafer to be placed of the plurality of wafers is less than a preset tolerance which is offset from respective center of said wafer to be placed; thereby, that is to say, a coverage of the imaginary circle defined by the light source should be slightly larger than an area of the wafer. As such, once the wafer is accurately located in place, at its expected position, then an optical path from the second light source 171 to the respective second sensor 172 will not be blocked.

By way of example, the predetermined tolerance is, for example, a length threshold which is pre-stored in the processing circuit 163 and adapted to define whether additional external device such as a robotic arm and the like may be ignored so as to correct an offset in the position of the wafer.

By way of example, the processing circuit 163 is also electrically connected with the plurality of second sensors 172, and is configured to receive the plurality of second electrical signals and to determine whether respective center of at least one wafer of the plurality of wafers is offset from the respective expected positions depending on the plurality of second electrical signals.

In a more specific embodiment, for example, each second sensor 172 is configured to generate a respective second electrical signal, which has one of a high level and a low level as a first magnitude of the respective second electrical signal in response to a condition where the second irradiation beam is not received thereby, and has the other one of the high level and the low level as a second magnitude of the respective second electrical signal in response to a condition where the second irradiation beam is at least partially received thereby. Moreover, the processing circuit 163 is configured to determine, depending on the plurality of second electrical signals output respectively by the plurality of second sensors 172, that respective center of at least one wafer of the plurality of wafers is offset from respective one of the expected positions of the plurality of wafers in response to the first magnitude of the respective second electrical signal from at least one second sensor of the plurality of second sensors 172.

In other words, if the wafer is normally and accurately located in place at the expected position thereof, its center is not offset from the expected position of the center thereof, then the optical path from the second light source 171 to the respective second sensor 172 will not be blocked; however, if the optical path from the second light source 171 to the respective second sensor 172 is blocked, then it may be determined that the center of the wafer is offset from the expected position of the center thereof.

In a further embodiment, for example, the chamber device 1 further comprises a distance sensor which is based on a photoelectric-conversion and is arranged concentric with the center of circle of the imaginary circle and adjacent to the plurality of second light sources, the distance sensor being configured to determine, depending on the second irradiation beam which is reflected from at least one of the plurality of wafers and then received by the distance sensor, a distance between the wafer at which the second irradiation beam is reflected back and the respective second light source. For example, the distance sensor is a laser ranging device. Thereby, in a condition that the processing circuit 163 determine that at least one wafer is offset from the respective one of the expected positions of the plurality of wafers, the processing circuit 163 is further configured to determine, depending on the distance as measured by the distance sensor, on which layer of the multi-layer supporting structure the respective wafer of the plurality of wafers is placed, whose center is offset from the respective one of the expected positions of the plurality of wafers.

For example, if a measured distance as measured by the distance sensor is substantially close to a distance from the second light source 171 to a layer, then it may be deduced that the center of the wafer placed on the layer deviates.

Further, when the first wafer detection device 16 detects the second magnitude of the respective first electrical signal, i.e., it may be possible that said layer is idle without any wafer thereon, or alternatively it may be possible that the wafer is offset from the expected position rather than being located in place normally.

In such a condition, on one hand, if the measured distance as measured by the distance sensor is substantially equal to or close to the distance from the second light source 171 to a layer, then it may be deduced that the center of the wafer placed on the layer deviates, and then it may be determined that, in fact, the layer is not idle (i.e., although the wafer is placed thereon, the optical path of the first irradiation beam may be at least partially blocked due to the offset of the wafer, the optical path of the first irradiation beam being not completely blocked), and depending on which wafer deviates (or is offset) as determined, a correction action may be performed by an external device such as a robotic arm and the like so as to make the wafer reset/return to the expected position thereof.

On the other hand, if the measured distance as measured by the distance sensor is still the distance from the second light source 171 to the second sensor 172, then it may be determined thereby that, in fact, the layer is idle indeed (without any wafer being placed thereon), and the layer may be used to accommodate the wafer additionally loaded. At this time, a portion of the first irradiation beam detected by the first wafer detection device 16 may actually be caused by, for example, an error trigger signal or a scattered light, and it is required to perform a maintenance on the wafer detection device and the chamber device 1 themselves.

Thereby, with a simple setting of the second wafer detection device 17 as above, it may be determined that, there must be a condition in which at least one wafer necessarily exists on a specific layer in the multi-layer supporting structure 13, such that in this condition, there is no need to perform a step of supplementary loading at least one additional wafer to said layer. That is to say, the second wafer detection device 17 functions as “a detector configured to detect a deviation/offset of central position of wafer”.

In a specific embodiment, for example, a plurality of second windows are formed through a side of the upper side and the lower side of the housing 10 where the plurality of second light sources 171 are mounted, and are aligned with the plurality of second light sources 171 respectively, such that the second irradiation beam emitted by the plurality of second light sources 171 respectively enters the cavity 10a through the plurality of second windows. And accordingly, the second light source 171 is arranged to be aligned with the second window and configured to emit the second irradiation beam into the cavity 10a through the second window.

As such, with such an arrangement, the second irradiation beam emitted by the light source 171 may be transferred into the cavity 10a without any obstruction.

For example, each second light source 171 comprises: a laser, an LED, or a hybrid light source of a laser and an LED.

Accordingly, for example, the plurality of sensors 162 (and possibly the distance sensor) are photosensitive sensors, e.g., photoelectric sensors or transducers each of which converts an optical signal of a specific wavelength (laser, LED light, or mixed light of both laser and LED light) into a respective electrical signal.

In addition, in a further embodiment of the present disclosure, there are different implementations in order to achieve mutual interference between the first irradiation beam and the second irradiation beam.

By way of example, in a condition that an axial direction of respective axes of the plurality of first pillars 142 and the plurality of second pillars 152 is set to be a longitudinal direction, then, in a transverse direction orthogonal to the longitudinal direction, both a minimal transverse distance between respective first pillars of the plurality of first pillars 142 and a minimal transverse distance between respective second pillars of the plurality of second pillars 152 in the same single layer of the multi-layer supporting structure are set to be not larger than a maximum transverse distance threshold which is defined to be a center distance of two light sources adj acent to each other in the transverse direction of the plurality of second light sources 171.

As such, with such a setting where the first light source 161 and the second light source 171 are spatially separated from each other, then, respective beams emitted by the first light source 161 and the second light source 171 respectively may not intersect and interfere with each other.

As another example, alternatively or additionally, for example, a wavelength range of a portion of the second irradiation beam received by the plurality of second sensors 172 and a wavelength range of a portion of the first irradiation beam received by the plurality of groups of first sensors 162 do not overlap with each other. Since these sensors are photosensitive sensors, for example, photoelectric sensors (e.g., photodiodes) each of which converts an optical signal of a specific wavelength into a respective electrical signal, then, the plurality of groups of first sensors 162 and the plurality of second sensors 172 receive light beams having different wavelengths.

For example, a wavelength range of the second irradiation beam emitted by the plurality of second light sources 171 is different from a wavelength range of the first irradiation beam emitted by the plurality of groups of first light sources 161. Moreover, for example, the wavelength range of the second irradiation beam emitted by the plurality of second light sources 171 and the wavelength range of the first irradiation beam emitted by the plurality of groups of first light sources 161 do not overlap with each other.

As such, due to a difference between wavelengths of irradiation beam detected by the first wafer detection device 16 and irradiation beam detected by the second wafer detection device 17 respectively, then, it is ensured that the irradiation beam detected by the first wafer detection device 16 and the irradiation beam detected by the second wafer detection device 17 may not interfere with each other.

FIG. 5 illustrates a schematic structural view of a wafer handling apparatus 20 according to embodiments of the disclosure.

In another aspect of embodiments of the present disclosure, as illustrated in FIG. 5, there is provided a wafer handling apparatus 20, comprising: the chamber device 1 as above; a first robotic arm 21 arranged in the first pressure environment and adjacent to the first valve 11, and configured to transfer the plurality of wafers between the first pressure environment and the chamber device 1 through the first valve 11; and a second robotic arm 22 arranged in the second pressure environment and adjacent to the second valve 12, and configured to transfer the plurality of wafers between the second pressure environment and the chamber device 1 through the second valve 12.

The wafer handling apparatus 20 comprises aforementioned chamber device 1, and accordingly has specific construction and corresponding technical effect similar to those of the latter, which will not be repeatedly discussed here.

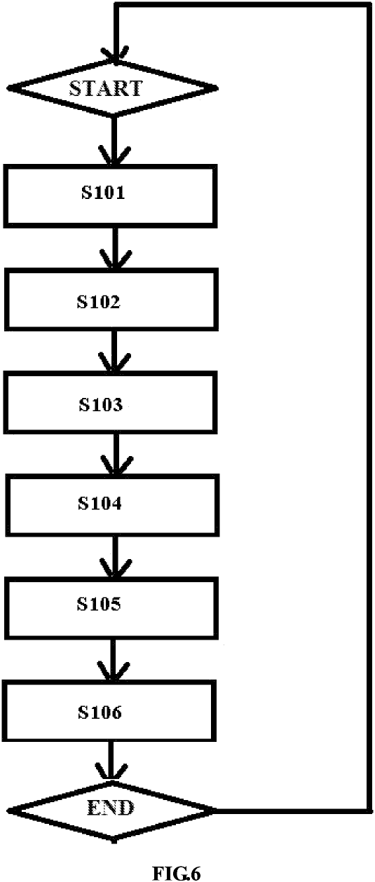

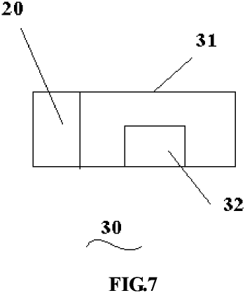

FIG. 6 illustrates a flowchart of a method for processing wafer using the wafer handling apparatus.

In still another aspect of the embodiment of the present disclosure, as illustrated in FIG. 6, there is provided a method for processing wafer using the wafer handling apparatus as above, comprising:
S101: opening the first valve 11 such that the first pressure environment and the cavity 10a are at substantially the same intensity of pressure, loading the plurality of wafers onto respective layers of the multi-layer supporting structure 13 via the first robotic arm 21, and adjusting respective positions of the plurality of wafers to the expected positions of the plurality of wafers depending on output of the processing circuit 163;
S102: cutting off the first valve 11 and vacuumizing the cavity 10a to a degree of vacuum which is substantially the same as that of the second pressure environment, after the plurality of wafers are loaded onto the multi-layer supporting structure 13; and
S103: opening the second valve 12 and transferring the plurality of wafers from the cavity 10a to the second pressure environment by the second robotic arm 22.

Furthermore, as an example, as illustrated, the method for processing wafer further comprises:
S104: transferring the plurality of wafers into the cavity 10a and loading the plurality of wafers onto respective layers of the multi-layer supporting structure 13 respectively by the second robotic arm 22, and adjusting the respective positions of the plurality of wafers to the expected positions of the plurality of wafers depending on the output of the processing circuit 163, after subsequent processes of the plurality of wafers in the second pressure environment are completed;
S105: cutting off the second valve 12 and inflating the cavity 10a to an intensity of pressure which is substantially the same as that of the first pressure environment; and
S106: opening the first valve 11 and transferring the plurality of wafers out of the cavity 10a to the first pressure environment by the first robotic arm 21.

The method for processing wafer uses the aforementioned chamber device 1 and the aforementioned wafer handling apparatus, and accordingly has specific construction and corresponding technical effect similar to those of the latter two, which will not be repeatedly discussed here.

FIG. 7 illustrates a schematic structural view of the electron beam detection apparatus 30 according to embodiments of the disclosure.

In yet another aspect of the embodiment of the present disclosure, as illustrated in FIG. 7, there is provided an electron beam detection apparatus 30, comprising: the wafer handling apparatus 20 as above; and a second housing 31, defining a vacuum chamber therein which functions as the second pressure environment, the vacuum chamber being equipped with an electron beam detection device 32 therein which comprises a scanning electron microscope.

The electron detection apparatus 30 comprises aforementioned chamber device 1, and aforementioned wafer handling apparatus 20, and accordingly has specific construction and corresponding technical effect similar to those of the latter two, which will not be repeatedly discussed here.

Thus, the embodiments of the present disclosure have the following superior technical effects:

In embodiments of the present disclosure, there is provided a chamber device 1 to function as a transition chamber, or to be referred to as “a vacuum interlock chamber” between different pressure environments (e.g., between an atmospheric chamber, and a vacuum chamber), in which a multi-layer supporting structure 13 is provided for supporting wafers in multiple layers, with two groups of detectors being disposed on the housing 10 and functioning as “detectors configured to detect existence of wafer” and “detectors configured to detect a deviation/offset of central position of wafer”, respectively, facilitating measurement of existence/presence of wafer in a certain layer of the multi-layer supporting structure 13 and whether there is a deviation/offset of the central position of the wafer from respective expected central position thereof in case of existence/presence of wafer. At the same time, the wafer is prevented from being contaminated and injured/damaged during the detection process. With relatively small volume of the chamber and a simplified structure, a detection which is non-destructive and free of contamination may be realized in the transition chamber, for detection of existence/presence of wafer and for detection whether the center of the wafer is accurately positioned.

In addition, according to aforementioned embodiments of the present disclosure, it can be understood that any technical solution formed by any combination of two or more embodiments also falls within the scope of protection of the present disclosure.

It should be understood that, orientation terms in the description of the present disclosure, such as “up”, “down”, “left”, “right”, and the like, are used to interpret orientation relationship as illustrated in the attached drawings. These orientation terms should not be interpreted as limitation of the scope of protection of the present disclosure.

The embodiments of the present disclosure are described in a progressive manner. Each embodiment focuses on the differences thereof as compared with other embodiments, and same or similar parts of various embodiments can be referred to each other.

The above are merely preferred embodiments of the invention and are not intended to limit the disclosure. Any modification, equivalent replacement, improvement, and the like made within the spirit and principles of the invention shall be contained in the protection scope of disclosure.

1. A chamber device which is configured to transfer a plurality of wafers between a first pressure environment and a second pressure environment, comprising:
a housing, which defines a cavity therein;
a first valve, provided on a first side of the housing, and configured to switch between a closed condition thereof, and an opened condition thereof where the housing is in communication with one of the first pressure environment and the second pressure environment therethrough;
a switching device, fixed to the housing, and configured to align the first valve with a respective inlet of the one of the first pressure environment and the second pressure environment;
a second valve, provided on a second side of the housing opposite to the first side, and configured to communicate the cavity with the first pressure environment or disconnect the cavity from the first pressure environment; and
a pressure regulating device, provided on the housing and in communication with the cavity, and configured to adapt an intensity of pressure within the cavity to be same as that of the first pressure environment or the second pressure environment,
wherein the chamber device further comprises a wafer supporting device provided inside the cavity and being formed into a multi-layer supporting structure, each layer of which is configured to support a respective wafer of the plurality of wafers respectively, in one-to-one correspondence.

2. The chamber device according to claim 1, wherein the multi-layer supporting structure comprises:
a first supporting half, comprising:
a first support fixed to a bottom inner surface of the housing and an inner wall at a third side of the housing intersecting both the first side and the second side; and
a plurality of first pillars protruding from the first support inwards the cavity, and
a second supporting half, comprising:
a second support fixed to the bottom inner surface of the housing and an inner wall at a fourth side of the housing opposite to the third side; and
a plurality of second pillars protruding from the second support inwards the cavity, and
wherein, respective first pillars of the plurality of first pillars and respective second pillars of the plurality of second pillars both located in each single layer of the multi-layer supporting structure jointly support the respective wafer of the plurality of wafers which is to be supported in a same single layer, and respective axes of the respective first pillars and the respective second pillars are arranged to be co-planar with each other and parallel to the bottom inner surface of the housing.

3. The chamber device according to claim 2,
wherein the first support comprises:
two first blocks, both being fixed on the inner wall at the third side of the housing and spaced apart from each other; and
a first rib connected between the two first blocks, and fixed to the bottom inner surface of the housing, and
wherein the second support comprises:
two second blocks, both being fixed on the inner wall at the fourth side of the housing and spaced apart from each other; and
a second rib connected between the two second blocks, and fixed to the bottom inner surface of the housing.

4. The chamber device according to claim 2, wherein each of both a distance between two adjacent first pillars, which are located respectively in two adjacent layers of the multi-layer supporting structure, of the plurality of first pillars, and a distance between two adjacent second pillars, which are located respectively in two adjacent layers of the multi-layer supporting structure, of the plurality of first pillars, is larger than a thickness of each wafer in the plurality of wafers; and
in a condition that an axial direction of respective axes of the plurality of first pillars and the plurality of second pillars is set to be a longitudinal direction, then, in a transverse direction orthogonal to the longitudinal direction, both a minimal transverse distance between respective first pillars of the plurality of first pillars and a minimal transverse distance between respective second pillars of the plurality of second pillars in a same single layer of the multi-layer supporting structure are set to be not less than a minimal transverse distance threshold which is defined to be a diameter of a wafer having a minimal dimensional specification in the plurality of wafers having different dimensional specifications which is bearable by the multi-layer supporting structure.

5. The chamber device according to claim 3, wherein each single layer of the multi-layer supporting structure is merely provided with: two respective first pillars of the plurality of first pillars, both being located on the two first blocks, respectively; and two respective second pillars of the plurality of second pillars, both being located on the two second blocks, respectively; and
in all layers of the multi-layer supporting structure, respective axes of first pillars located on a same first block of the two first blocks respectively are arranged to be co-planar with each other, and/or respective axes of second pillars located on a same second block of the two second blocks respectively are arranged to be co-planar with each other.

6. The chamber device according to claim 3, wherein the first rib and the two first blocks are formed integrally with each other, and/or
wherein the second rib and the two second blocks are formed integrally with each other.

7. The chamber device according to claim 2, further comprising a first wafer detection device, which comprises:
a first light source, mounted to the housing and configured to emit a first irradiation beam into the cavity;
a plurality of groups of first sensors mounted to the housing and arranged to be at least partially aligned in one-to-one correspondence with layers of the multi-layer supporting structure respectively, and configured to sense the first irradiation beam and in turn generate a plurality of first electrical signals based on sensed results; and
a processing circuit, electrically connected with the plurality of groups of first sensors, and configured to receive the plurality of first electrical signals and to determine whether a respective single layer of the multi-layer supporting structure provided corresponding to each group of the plurality of groups of first sensors supports therein a respective wafer of the plurality of wafers, based on the plurality of first electrical signals.

8. The chamber device according to claim 7, wherein each group of the plurality of groups of first sensors is configured to generate a respective first electrical signal, which has one of a high level and a low level as a first magnitude of the respective first electrical signal in response to a condition where the first irradiation beam is not received thereby, and has the other one of the high level and the low level as a as a second magnitude of the respective first electrical signal in response to a condition where the first irradiation beam is at least partially received thereby; and
the processing circuit is configured to determine, depending on the respective first electrical signal output by group of the plurality of groups of first sensors at least partially aligned in one-to-one correspondence with a respective layer in the multi-layer supporting structure, that said layer supports the respective wafer thereon in response to the first magnitude of the respective first electrical signal and said layer fails to support the respective wafer thereon in response to the second magnitude of the respective first electrical signal.

9. The chamber device according to claim 7, wherein the first support is provided with a notch opening towards an upper surface of the housing, and the third side is formed with a first window therethrough which at least partially overlaps with the notch; and
the first light source is arranged to be aligned with the first window and configured to emit the first irradiation beam into the cavity through the first window.

10. The chamber device according to claim 7, further comprising a second wafer detection device, which comprises:
a plurality of second light sources, mounted on one of upper side and lower side of the housing, and arranged to define an imaginary circle having a center of circle coincident with respective expected positions of respective centers of circle of the plurality of wafers, the plurality of second light sources being arranged to spaced apart from each other at a same angular interval in a circumferential direction of the imaginary circle and configured to emit a second irradiation beam into the cavity respectively; and
a plurality of second sensors, provided on the other one of the upper side and lower side , and substantially aligned in one-to-one correspondence with the plurality of second light sources, and configured to sense respectively the second irradiation beam from the plurality of second light sources so as to generate a plurality of second electrical signals based thereon,
wherein the plurality of second light sources are arranged such that a difference between a distance between respective centers of the plurality of second light sources and the center of circle of the imaginary circle and a radius of the wafer to be placed of the plurality of wafers is less than a preset tolerance which is offset from respective center of said wafer to be placed, and
the processing circuit is also electrically connected with the plurality of second sensors, and is configured to receive the plurality of second electrical signals and to determine whether respective center of at least one wafer of the plurality of wafers is offset from the respective expected positions depending on the plurality of second electrical signals.

11. The chamber device according to claim 10, wherein each second sensor is configured to generate a respective second electrical signal, which has one of a high level and a low level as a first magnitude of the respective second electrical signal in response to a condition where the second irradiation beam is not received thereby, and has the other one of the high level and the low level as a second magnitude of the respective second electrical signal in response to a condition where the second irradiation beam is at least partially received thereby; and
the processing circuit is configured to determine, depending on the plurality of second electrical signals output respectively by the plurality of second sensors, that respective center of at least one wafer of the plurality of wafers is offset from respective one of the expected positions of the plurality of wafers in response to the first magnitude of the respective second electrical signal from at least one second sensor of the plurality of second sensors.

12. The chamber device according to claim 11, further comprising a distance sensor which is based on a photoelectric-conversion and is arranged concentric with the center of circle of the imaginary circle and adjacent to the plurality of second light sources, the distance sensor being configured to determine, depending on the second irradiation beam which is reflected from at least one of the plurality of wafers and then received by the distance sensor, a distance between the wafer at which the second irradiation beam is reflected back and the respective second light source; and
in a condition that the processing circuit determine that at least one wafer is offset from the respective one of the expected positions of the plurality of wafers, the processing circuit is further configured to determine, depending on the distance as measured by the distance sensor, on which layer of the multi-layer supporting structure the respective wafer of the plurality of wafers is placed, whose center is offset from the respective one of the expected positions of the plurality of wafers.

13. The chamber device according to claim 10, wherein a plurality of second windows are formed through a side of the upper side and the lower side of the housing where the plurality of second light sources are mounted, and are aligned with the plurality of second light sources respectively, such that the second irradiation beam emitted by the plurality of second light sources respectively enters the cavity through the plurality of second windows.

14. The chamber device according to claim 10, wherein in a condition that an axial direction of respective axes of the plurality of first pillars and the plurality of second pillars is set to be a longitudinal direction, then, in a transverse direction orthogonal to the longitudinal direction, both a minimal transverse distance between respective first pillars of the plurality of first pillars and a minimal transverse distance between respective second pillars of the plurality of second pillars in a same single layer of the multi-layer supporting structure are set to be not larger than a maximum transverse distance threshold which is defined to be a center distance of two light sources adjacent to each other in the transverse direction of the plurality of second light sources.

15. The chamber device according to claim 10, wherein a wavelength range of a portion of the second irradiation beam received by the plurality of second sensors and a wavelength range of a portion of the first irradiation beam received by the plurality of groups of first sensors do not overlap with each other.

16. The chamber device according to claim 7, wherein the pressure regulating device comprises:
an inflation port, connected to a gas source or the first pressure environment, and configured to inflate the cavity to an intensity of pressure which is substantially equalized with that of the first pressure environment;
an gas-suction port, connected to a vacuum source or the second pressure environment, and configured to vacuumize the cavity to a degree of vacuum which is set by the processing circuit or is substantially same as that of the second pressure environment; and
a vacuum gauge, which communicates with the cavity, and is configured to measure the degree of vacuum of the cavity,
wherein vacuumizing of the cavity through the gas-suction port is controlled, depending on results of measurement by the vacuum gauge.

17. A wafer handling apparatus, comprising:
the chamber device according to claim 12;
a first robotic arm arranged in the first pressure environment and adjacent to the first valve, and configured to transfer the plurality of wafers between the first pressure environment and the chamber device through the first valve; and
a second robotic arm arranged in the second pressure environment and adjacent to the second valve, and configured to transfer the plurality of wafers between the second pressure environment and the chamber device through the second valve.

18. A method for processing wafer using the wafer handling apparatus according to claim 17, comprising:
opening the first valve such that the first pressure environment and the cavity are at substantially a same intensity of pressure, loading the plurality of wafers onto respective layers of the multi-layer supporting structure via the first robotic arm respectively, and adjusting respective positions of the plurality of wafers to the expected positions of the plurality of wafers depending on output of the processing circuit;
cutting off the first valve and vacuumizing the cavity to a degree of vacuum which is substantially same as that of the second pressure environment, after the plurality of wafers are loaded onto the multi-layer supporting structure; and
opening the second valve and transferring the plurality of wafers from the cavity to the second pressure environment by the second robotic arm.

19. The method for processing wafer according to claim 18, further comprising:
transferring the plurality of wafers into the cavity and loading the plurality of wafers onto respective layers of the multi-layer supporting structure respectively by the second robotic arm, and adjusting the respective positions of the plurality of wafers to the expected positions of the plurality of wafers depending on the output of the processing circuit, after subsequent processes of the plurality of wafers in the second pressure environment are completed;
cutting off the second valve and inflating the cavity to an intensity of pressure which is substantially same as that of the first pressure environment; and
opening the first valve and transferring the plurality of wafers out of the cavity to the first pressure environment by the first robotic arm.

20. An electron beam detection apparatus, comprising:
the wafer handling apparatus according to claim 17; and
a second housing, defining a vacuum chamber therein which functions as the second pressure environment, the vacuum chamber being equipped with an electron beam detection device therein which comprises a scanning electron microscope.
